(19) United States
(12) Patent Application Publication
(10) Pub. No.: US 2010/0295133 A1
(43) Pub. Date: Nov. 25, 2010

(54) Resistor of Semiconductor Device and Method of Forming the Same

(75) Inventor: Jum Soo Kim, Icheon-si (KR)

Correspondence Address: MARSHALL, GERSTEIN & BORUN LLP, 233 SOUTH WACKER DRIVE, 6300 WILLIS TOWER, CHICAGO, IL, 60606-6357, US

(73) Assignee: HYNIX SEMICONDUCTOR INC., Icheon-si (KR)

(21) Appl. No.: 12/773,295

(22) Filed: May 4, 2010

(30) Foreign Application Priority Data
May 25, 2009 (KR) 10-2009-0045403

(51) Int. Cl. H01L 27/105; H01L 21/02

(52) U.S. Cl. 257/380; 438/384; 257/E27.071; 257/E21.004

(57) ABSTRACT

The resistor of a semiconductor device comprises a semiconductor substrate comprising isolation layers and active regions, a gate insulating layer and a first polysilicon layer formed over the active region, a second polysilicon layer separated into a first pattern formed on the isolation layer, and a second pattern formed over the first polysilicon layer and higher than the first pattern, a first interlayer dielectric layer covering the first pattern over the isolation layer, a second interlayer dielectric layer formed over the first interlayer dielectric layer, contact holes exposing the first pattern in the first and second interlayer dielectric layers, and contact plugs filling the respective contact holes and coupled to the first pattern.

### CROSS-REFERENCE TO RELATED APPLICATION

Priority to Korean patent application number 10-2009-0045403 filed May 25, 2009, the entire disclosure of which is incorporated by reference herein, is claimed.

### BACKGROUND

Exemplary embodiments relate generally to a resistor of a semiconductor device and a method of forming the same and, more particularly, to the resistor of a semiconductor device, formed in a peripheral region, and a method of forming the same.

A semiconductor device includes a memory cell array region and a peripheral region. The memory cell array region is a region in which a number of memory cells for storing data are formed. The peripheral region is a region in which circuit elements, such as a power supply circuit having a resistor and a control circuit for controlling the respective program, erase, and read operations of a memory cell are formed.

In general, the resistor formed in the peripheral region preferably is formed using a junction resistor, a poly resistor, or a metal resistor. Of these, the junction resistor is sensitive to temperature, and it has a great shift in the resistance value because of a narrow width. It is difficult to construct a metal resistor having a high resistance value because metal resistors inherently have a low resistance value. Accordingly, the poly resistor having a small shift in temperature and voltage preferably is used to construct a resistor having a high resistance value.

FIG. 1 is a plan view of a prior art poly resistor. FIG. 2 is a cross-sectional view of the poly resistor taken along line I-I′ in FIG. 1. Although a memory cell array region is not shown, the poly resistor is formed using a process of forming memory cells in the memory cell array region.

Referring to FIGS. 1 and 2, a semiconductor substrate 11 includes isolation regions B in which isolation layers 17 are formed and active regions A in which the isolation layers 17 are not formed. The active regions A are parallel to the isolation layers 17. A gate insulating layer 13 and a first polysilicon layer 15 are stacked over the active region A. Furthermore, a dielectric layer 19, a second polysilicon layer 21, and a metal silicide layer 22 are stacked over the active region A with the gate insulating layer 13 and the first polysilicon layer 15 interposed therebetween. The stack structures, each including a dielectric layer 19, a second polysilicon layer 21, and a metal silicide layer 22, are formed over the isolation regions B as well as over the active regions A. Meanwhile, the stack structures, each including a dielectric layer 19, a second polysilicon layer 21, and a metal silicide layer 22, are formed in separated patterns so that the first polysilicon layer 15 can be exposed.

An interlayer dielectric layer 23 is formed over the semiconductor substrate 11 in which the stack structures, each including a dielectric layer 19, a second polysilicon layer 21, and a metal silicide layer 22, and the first polysilicon layer 15 are formed. The interlayer dielectric layer 23 includes contact holes 25 to expose the first polysilicon layer 15 between the stack structures, each including a dielectric layer 19, a second polysilicon layer 21, and a metal silicide layer 22. Furthermore, contact plugs 27 coupled to the first polysilicon layer 15 are formed within the respective contact holes 25 included in the interlayer dielectric layer 23. The contact plugs 27 are coupled to a metal line (not shown) to be formed on the interlayer dielectric layer 23. That is, the contact plugs 27 electrically couple the metal line and the first polysilicon layer 15 which is used as a resistor.

In the construction described above, the first polysilicon layer 15, the dielectric layer 19, the second polysilicon layer 21, and the metal silicide layer 22 are used to form memory cell gates in the memory cell array region. More particularly, the memory cell gate of a NAND flash memory device has a stack structure of a floating gate, the dielectric layer 19, and a control gate. The first polysilicon layer 15 is a conductive layer used as the floating gate, and the second polysilicon layer 21 and the metal silicide layer 22 are conductive layers used as the control gate. In particular, the metal silicide layer 22 is used to improve the resistance of the control gate.

A data program operation is performed by injecting electrons into the floating gate using the Fowler-Nordheim (FN) tunneling phenomenon. Accordingly, the first polysilicon layer 15 used as the floating gate has a close relationship with the characteristics of the semiconductor device, and is likely to have a varying resistance. For example, if the concentration of impurities implanted into the first polysilicon layer 15 is changed to prevent the occurrence of an abnormally-programmed memory cell, the resistance of the first polysilicon layer 15 can vary. Thus, if a resistor is formed using the first polysilicon layer 15, it is difficult to maintain a stable resistance value. To secure a stable resistance value, the layout and circuit design of the resistor formed using the first polysilicon layer 15 must be changed.

Furthermore, the width of the first polysilicon layer 15 is difficult to control because the first polysilicon layer 15 is formed when trenches to define the regions in which the isolation layers 17 will be formed are etched. Accordingly, if the first polysilicon layer 15 is used to form the resistor, the ability to control resistance is weakened.

### BRIEF SUMMARY

Exemplary embodiments relate to a resistor of a semiconductor device and a method of forming the same, which are capable of stably securing the resistance of the resistor.

The resistor of a semiconductor device according to an aspect of the disclosure comprises a semiconductor substrate that comprises isolation layers and active regions, a gate insulating layer and a first polysilicon layer formed over the active region, a second polysilicon layer separated into a first pattern formed on the isolation layer, and a second pattern formed over the first polysilicon layer and higher than the first pattern, a first interlayer dielectric layer covering the first pattern over the isolation layer, a second interlayer dielectric layer formed over the first interlayer dielectric layer, contact holes exposing the first pattern in the first and second interlayer dielectric layers, and contact plugs filling the respective contact holes and coupled to the first pattern.

A method of manufacturing the resistor of a semiconductor device according to another aspect of the disclosure comprises forming a gate insulating layer and a first polysilicon layer over an active region of a semiconductor substrate that comprises isolation regions and active regions, and forming an isolation layer in the isolation region, forming a second polysilicon layer over the first polysilicon layer and the isolation layer, etching the second polysilicon layer to separate the second polysilicon layer into a first pattern formed on the isolation layer and a second pattern formed over the first polysilicon layer and higher than the first pattern, forming a first interlayer dielectric layer, covering the first pattern over the isolation layer, forming a second interlayer dielectric layer over the first interlayer dielectric layer, forming contact holes in the first and second interlayer dielectric layers to expose the first pattern, and forming contact plugs coupled to the first pattern, within the respective contact holes.

Forming the gate insulating layer and the first polysilicon layer over an active region of the semiconductor substrate preferably comprises stacking the gate insulating layer and the first polysilicon layer over the isolation region and the active region, etching the isolation region, including the first polysilicon layer, the gate insulating layer, and the semiconductor substrate, forming the isolation layer in the etched isolation region, and lowering the height of the isolation layer to be lower than a height of the first polysilicon layer.

The isolation layer preferably is lower than the first polysilicon layer to define a step between the first polysilicon layer and the isolation layer. When forming the second interlayer dielectric layer over the first interlayer dielectric layer, the second polysilicon layer preferably is lower over the isolation layer than over the first polysilicon layer because of the step.

The step preferably has a thickness of 500 ∈ to 1500 Å.

The method preferably further comprises, before forming the second polysilicon layer, forming a dielectric layer on the isolation layer and the first polysilicon layer and removing the dielectric layer formed on the isolation layer.

Removing the dielectric layer formed on the isolation layer preferably comprises forming a capping layer on the dielectric layer formed on the first polysilicon layer and etching the dielectric layer using the capping layer as a barrier.

The method preferably further comprises etching the second polysilicon layer formed over the isolation layer the first interlayer dielectric layer, before separating the second polysilicon layer into the first and second patterns after forming the second polysilicon layer.

Forming a first interlayer dielectric layer covering the first pattern over the isolation layer preferably comprises forming the first interlayer dielectric layer over the isolation layer and the second pattern, polishing a surface of the first interlayer dielectric layer to expose the second pattern, and forming a metal silicide layer on the second pattern.

The method preferably further comprises lowering a height of the first interlayer dielectric layer so that sidewalls of the second pattern are exposed, before forming the metal silicide layer after polishing the surface of the first interlayer dielectric layer.

When forming the second polysilicon layer, the second polysilicon layer preferably is formed to a thickness of 700 Å to 2000 Å.

### BRIEF DESCRIPTION OF THE DRAWINGS

FIG. 1 is a plan view of a poly resistor;

FIG. 2 is a cross-sectional view of the poly resistor taken along line I-I′ in FIG. 1;

FIG. 3 is a plan view of the resistor of a semiconductor device according to an exemplary embodiment of the disclosure;

FIGS. 4A to 4H are cross-sectional views illustrating a method of forming the resistor of the semiconductor device according to an exemplary embodiment of the disclosure; and

FIGS. 5A and 5B are cross-sectional views illustrating a method of forming the resistor of a semiconductor device according to another exemplary embodiment of the disclosure.

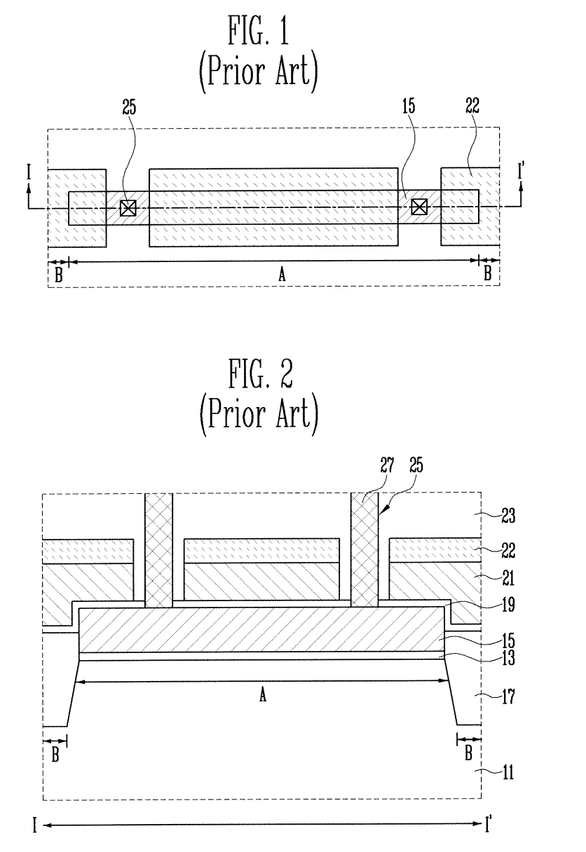

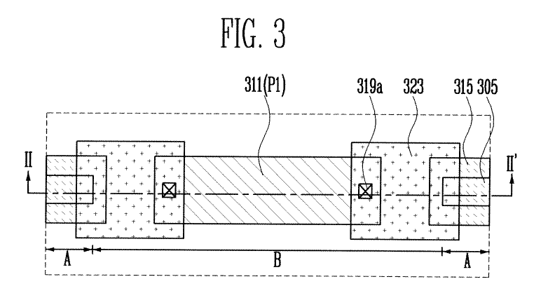

### DESCRIPTION OF EMBODIMENTS

Hereinafter, exemplary embodiments of the disclosure are described in detail with reference to the accompanying drawings. The drawing figures are provided to allow those having ordinary skill in the art to understand the scope of the embodiments of the disclosure.

FIG. 3 is a plan view of the resistor of a semiconductor device according to an exemplary embodiment of the disclosure.

Referring to FIG. 3, the resistor according to the exemplary embodiment of the disclosure includes contact pads 323 and a first pattern P1. The first pattern P1 is electrically coupled to a metal line (not shown), formed over the contact pads 323, through contact plugs formed respective contact holes 319a. The first pattern P1 is formed in each of the isolation regions B of the semiconductor substrate and is separated from a first polysilicon layer 305 and a metal silicide layer 315, which are formed in the active region A of the semiconductor substrate.

The first pattern P1, the first polysilicon layer 305, and the metal silicide layer 315 are formed using a process of forming a memory cell array in a memory cell array region (not shown). Although not shown, the memory cell array includes a memory cell gate having a stack structure of a floating gate, a dielectric layer, and a control gate.

The first pattern P1 is formed using a second polysilicon layer 311 used as the control gate. The first polysilicon layer 305 is a conductive layer used as the floating gate. The metal silicide layer 315 is stacked over the second polysilicon layer 311 and is a conductive layer used as the control gate along with the second polysilicon layer 311. The metal silicide layer 315 improves the resistance of the control gate.

The metal silicide layer 315 is formed using an annealing process performed on a metal layer stacked over the second polysilicon layer 311 such that metal from the metal layer is diffused into the second polysilicon layer 311. The metal silicide layer 315 includes a tungsten silicide (WSiₓ) layer or a cobalt silicide (CoSiₓ) layer. The metal silicide layer 315 lowers the resistance of the control gate. The metal silicide layer 315 preferably is not included in the first pattern P1 which must have a high and stable resistance because the metal silicide layer is formed through the diffusion of metal.

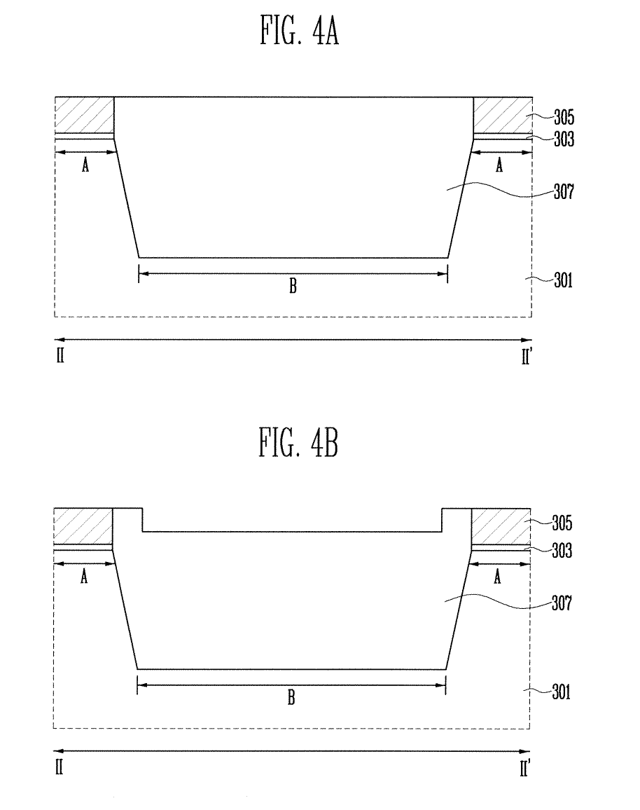

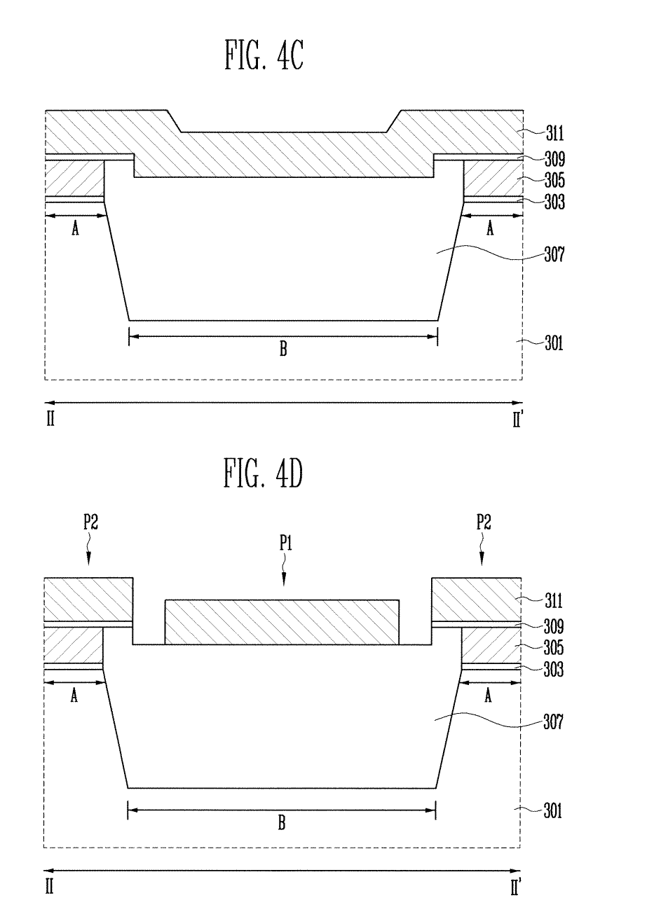

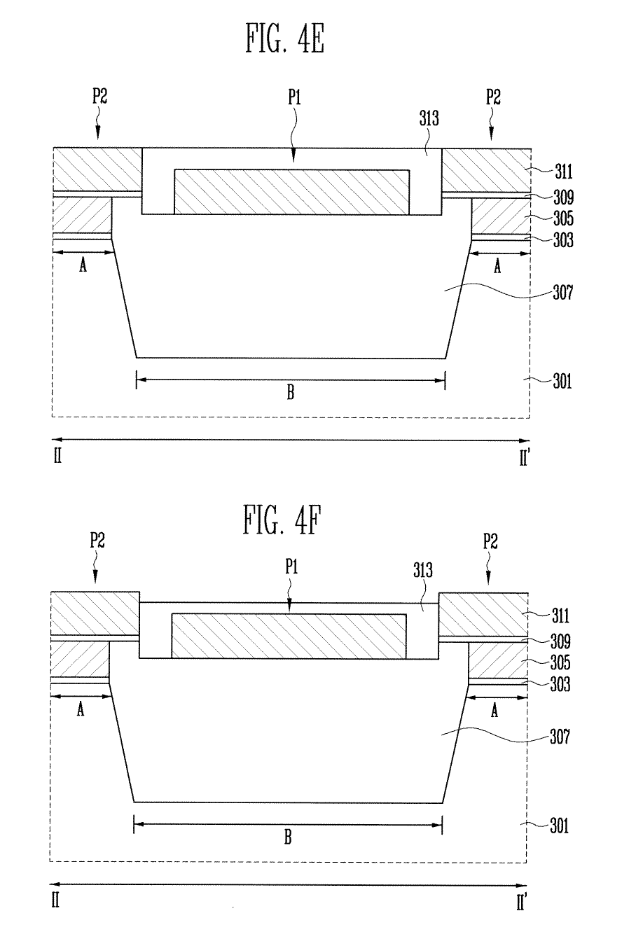

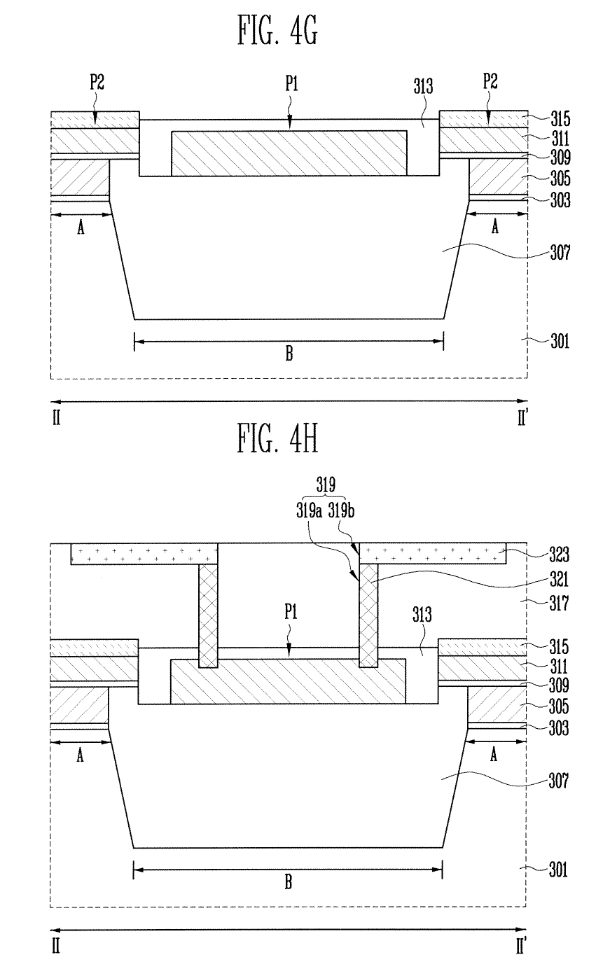

In the embodiment of the disclosure, although the first pattern P1 is formed using a conductive layer used as the control gate, the metal silicide layer 315 is not formed over the first pattern P1 using an existing process of forming a memory cell array. Accordingly, an additional mask process to remove the metal silicide layer 315 formed over the first pattern P1 need not to be performed to secure a high and stable resistance. This is described in detail with reference to FIGS. 4A to 4H.

Furthermore, in the embodiment of the disclosure, the first pattern P1 used as a resistor is not formed using the first polysilicon layer 305 for a floating gate, which is pertinent to the cell characteristics, but is formed using the second polysilicon layer 311 for a control gate which is less related to control of the cell characteristics. Accordingly, a stable resistance can be secured. In other words, although the doping concentration of impurities of the first polysilicon layer 305 is changed to control the cell characteristics, the resistor formed using the second polysilicon layer 311 can secure a stable resistance. Accordingly, in the embodiment of the disclosure, although the doping concentration of the first polysilicon layer 305 to control the cell characteristics, the layout and circuit design of the resistor need not be changed.

Furthermore, since the first pattern P1 used as the resistor is formed in the isolation region B, parasitic capacitance occurring in the active region A can be improved.

A method of forming a semiconductor device including the above-described resistor is described in detail below.

FIGS. 4A to 4H are cross-sectional views illustrating a method of forming the resistor of the semiconductor device according to an exemplary embodiment of the disclosure. FIGS. 4A to 4H are cross-sectional views of the semiconductor device taken along line H II′ in FIG. 3.

Referring to FIG. 4A, first, a gate insulating layer 303 and a first polysilicon layer 305 are formed over an active region A of a semiconductor substrate 301, including isolation regions B and the active regions A. The isolation layer 307 is formed in the isolation region B.

The method of forming the gate insulating layer 303 and the first polysilicon layer 305 over the active region A and forming the isolation layer 307 in the isolation region B is described in more detail. The gate insulating layer 303 and the first polysilicon layer 305 are formed over the semiconductor substrate 301. The gate insulating layer 303 preferably is formed of an oxide layer and preferably is formed through an oxidization process. The gate insulating layer 303 formed through the oxidization process preferably is formed of a silicon oxide (SiO₂) layer. The first polysilicon layer 305 is a conductive layer used as a floating gate for storing electric charges.

A trench is formed in the isolation region B by etching the first polysilicon layer 305, the gate insulating layer 303, and the semiconductor substrate 301. The trench is filled with insulating material to form the isolation layer 307. The trench preferably is formed by forming an isolation hard mask pattern over the first polysilicon layer 305 and performing an etch process using the isolation hard mask pattern as an etch barrier. The isolation hard mask pattern can be removed after the isolation layer 307 is formed. The isolation layer 307 preferably is formed by forming an insulating layer having a thickness enough to fill the trench formed in the isolation region B and polishing a surface of the insulating layer until the first polysilicon layer 305 is exposed. The polishing process preferably is performed using a chemical mechanical polishing (CMP) process. Here, regions of the semiconductor substrate 301 in which the isolation layer 307 is not formed are defined as the active regions A. Through the processes, the gate insulating layer 303 and the first polysilicon layer 305 remain only over the active regions A. Meanwhile, the processes described with reference to FIG. 4A are also performed in the memory cell array region.

Referring to FIG. 4B, the isolation layer 307 is etched so that the height of the isolation layer 307 becomes lower than the height of the first polysilicon layer 305. Thus, a step is defined by the isolation layer 307 and the first polysilicon layer 305. In this case, the height of the isolation layer 307 is lower than that of the first polysilicon layer 305, but preferably is higher than that of the gate insulating layer 303. To this end, the step defined by the isolation layer 307 and the first polysilicon layer 305 preferably is formed 500 Å to 1500 Å.

Meanwhile, the process described with reference to FIG. 4B is performed simultaneously with an etch process for controlling the effective field oxide height (EFH) of the isolation layer to improve the coupling ratio between the floating gate and the control gate in the memory cell array region.

Referring to FIG. 4C, a dielectric layer 309 is formed on the isolation layer 307 and the first polysilicon layer 305. The dielectric layer 309 formed on the isolation layer 307 is removed. The dielectric layer 309 preferably has a stack structure of an oxide layer/a nitride layer/an oxide layer. Furthermore, the dielectric layer 309 preferably is formed simultaneously with a dielectric layer formed over the floating gate in the memory cell array region. In the memory cell array region, the dielectric layer constituting the gate of a source select transistor and a drain select transistor includes a gate contact hole to expose the first polysilicon layer. The process of removing the dielectric layer 309 formed on the isolation layer 307 preferably is performed simultaneously with a process of forming the gate contact hole included in the dielectric layer in the memory cell array region. For reference, in the region in which the source select transistor and the drain select transistor are formed, the first polysilicon layer and the second polysilicon layer can be electrically coupled together through the gate contact hole.

After the dielectric layer 309 formed on the isolation layer 307 is removed as described above, the second polysilicon layer 311 is formed on the dielectric layer 309 and the isolation layer 307. The second polysilicon layer 311 preferably is formed to be lower on the isolation layer 307 than on the first polysilicon layer 305 because of the step defined by the isolation layer 307 and the first polysilicon layer 305. The step of the second polysilicon layer 311 formed on the first polysilicon layer 305, and the second polysilicon layer 311 formed on the isolation layer 307, can be further increased by removing the dielectric layer 309 formed on the isolation layer 307. To further increase the step of the second polysilicon layer 311 formed on the first polysilicon layer 305, and the second polysilicon layer 311 formed on the isolation layer 307, the second polysilicon layer 311 formed on the isolation layer 307 can be etched.

Meanwhile, to maintain the step of the second polysilicon layer 311 formed on the first polysilicon layer 305, and the second polysilicon layer 311 formed on the isolation layer 307, 300 Å or more, the second polysilicon layer 311 preferably is formed to a thickness of 700 Å to 2000 Å. The second polysilicon layer 311 preferably is formed simultaneously with a second polysilicon layer which constitutes a conductive layer for the control gate of a memory cell in the memory cell array region.

Referring to FIG. 4D, the second polysilicon layer 311 is etched and separated into the first pattern P1 formed on the isolation layer 307 and a second pattern P2 formed higher than the first pattern P1 and formed over the first polysilicon layer 305. The process of separating the second polysilicon layer 311 into the first pattern P1 and the second pattern P2 preferably is performed simultaneously with a process of separating the structure in which the first polysilicon layer, the dielectric layer, and the second polysilicon layer are stacked in the memory cell array region into a number of patterns.

Referring to FIG. 4E, a first interlayer dielectric layer 313 covering the first pattern P1 is formed over the isolation layer 307. The first interlayer dielectric layer 313 preferably is formed by forming an insulating layer to cover the first pattern P1 and the second pattern P2 and polishing a surface of the insulating layer until the second pattern P2 is exposed. The polishing process preferably is performed using a CMP process.

Referring to FIG. 4F, the sidewalls of the second pattern P2 can be exposed by performing an etch process to lower the height of the first interlayer dielectric layer 313.

Referring to FIG. 4G, the metal silicide layer 315 is formed on the second pattern P2. The metal silicide layer 315 preferably is formed by forming a metal layer on the exposed surface of the second pattern P2 and then performing an annealing process so that metal from the metal layer is diffused into the second polysilicon layer 311 constituting the second pattern P2. Accordingly, as described above with reference to FIG. 4F, in the case in which the sidewalls of the second pattern P2 are exposed by lowering the height of the first interlayer dielectric layer 313 than the height of the second pattern P2, the metal silicide layer 315 preferably is formed more readily because the contact area of the metal layer and the second polysilicon layer 311 is increased.

Meanwhile, the first pattern P1 can be protected by the first interlayer dielectric layer 313 because it is lower than the second pattern P2 although an additional mask process is not performed. Accordingly, when the metal silicide layer 315 is formed, the metal from the metal layer cannot be diffused into the first pattern P1 because the first pattern P1 is precluded by the first interlayer dielectric layer 313. To more effectively prevent the metal of the metal layer from diffusing into the first pattern P1 using the first interlayer dielectric layer 313, the thickness of the first interlayer dielectric layer 313 formed on the first pattern P1 preferably can be increased. To this end, the step between the first pattern P1 and the second pattern P2 preferably can be increased using the process described with reference to FIG. 4C.

Meanwhile, the process of forming the metal silicide layer 315 on the exposed surface of the second pattern P2 preferably is performed simultaneously with a process of forming a metal silicide layer on the second polysilicon layer used as the control gate of the memory cell array.

Referring to FIG. 4H, a second interlayer dielectric layer 317 covering the first pattern P1 and the second pattern P2 is formed over the first interlayer dielectric layer 313.

The second interlayer dielectric layer 317 is etched to form contact holes 319a, exposing the first pattern P1, in the second interlayer dielectric layer 317. Contact plugs 321 coupled to the first pattern P1 are formed within the respective contact holes 319a by filling the inside of the contact holes 319a with conductive material.

Pad holes 319b, each having a width wider than the contact hole 319a, are formed over the respective contact holes 319a by etching the second interlayer dielectric layer 317. The inside of the pad holes 319b is filled with conductive material, thereby forming pad contacts 323 coupled to the respective contact holes 319a.

The contact plugs 321 and the pad contacts 323 preferably are formed by forming a damascene pattern 319, including the contact holes 319a and the pad holes 319b, in the second interlayer dielectric layer 323 and filling the inside of the damascene pattern 319 with conductive material.

After the contact plugs 321 and the pad contacts 323 are formed, a metal line (not shown) coupled to the pad contacts 323 preferably is formed using any suitable process.

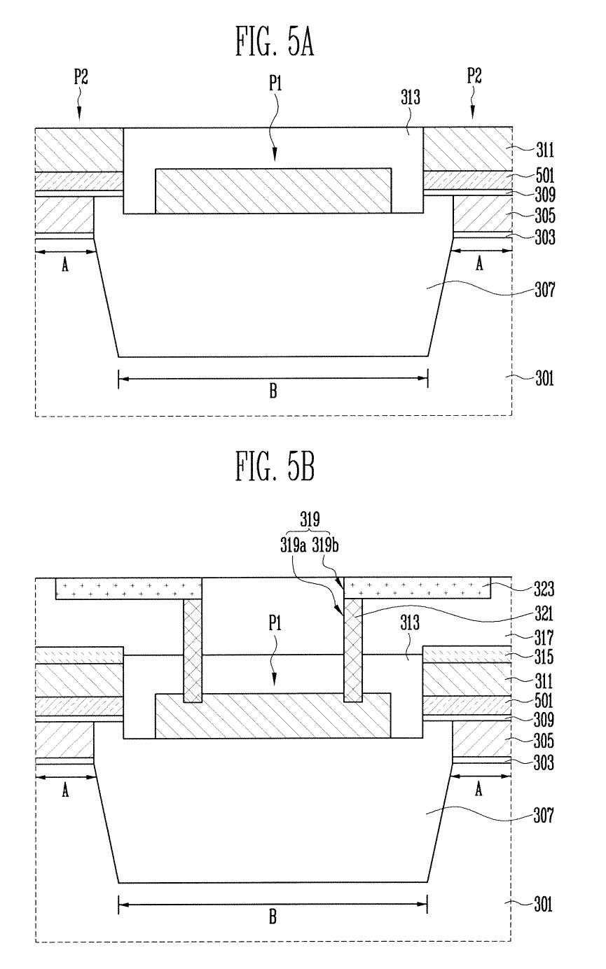

FIGS. 5A and 5B are cross-sectional views illustrating a method of forming the resistor of a semiconductor device according to another exemplary embodiment of the disclosure.

Referring to FIG. 5A, a gate insulating layer 303 and a first polysilicon layer 305 are formed over active region A and an isolation layer 307 is formed in an isolation region B, using the same method as that described with reference to FIGS. 4A and 4B. The height of the isolation layer 307 is lowered.

Next, a dielectric layer 309 is formed in the same manner as that described with reference to FIG. 4C. A capping layer 501 is formed on the dielectric layer 309 using a polysilicon layer. The capping layer 501 can be patterned using a hard mask pattern. Here, the hard mask pattern preferably is a photoresist pattern formed through a photolithography process.

An etch process using the capping layer 501 as a barrier is performed so that the dielectric layer 309 formed on the isolation layer 307 of the isolation region is removed. Next, a second polysilicon layer 311 is formed over the capping layer 501.

The capping layer 501 acts as a barrier in an etch process for forming gate contact holes in a dielectric layer constituting the gate of a source select transistor and a drain select transistor in a memory cell array region. Thus, the capping layer 501 protects the dielectric layer that must remain in the regions in which memory cells are formed. Further, the capping layer 501 can further increase the size of the step of the second polysilicon layer 311 formed over the first polysilicon layer 305 and the second polysilicon layer 311 formed over the isolation layer 307.

Next, the second polysilicon layer 311 is separated into a first pattern P1 and second pattern P2 in the same manner as that described with reference to FIG. 4D. When a first interlayer dielectric layer 313 is formed in the same manner as that described with reference to FIG. 4E, the thickness of the first interlayer dielectric layer 313 over the first pattern P1 can be thicker than that shown in FIG. 4E.

Referring to FIG. 5B, a metal silicide layer 315, a second interlayer dielectric layer 317, contact holes 319a, contact plugs 321, pad holes 319b, and pad contacts 323 are formed in the same manner as that described with reference to FIGS. 4F to 4H. Meanwhile, since the thickness of the first interlayer dielectric layer 313 formed over the first pattern P1 can be thicker than that shown in FIG. 4E, the diffusion of metal into the first pattern P1 when the metal silicide layer 315 is formed can be effectively prevented.

The resistor of the disclosure preferably is applied to a resistor having a resistance of 100 ohm to 500 ohm.

According to the disclosure, the resistor is formed using the polysilicon layer formed over the dielectric layer of a memory cell gate. Here, the polysilicon layer formed over the dielectric layer of the memory cell gate is involved with control of the cell characteristics. Accordingly, the disclosure can secure a stable resistance irrespective of control of the cell characteristics. Further, although the doping concentration of impurities of the polysilicon layer formed under the dielectric layer is changed, the layout and circuit design of a resistor need not be changed to secure a stable resistance. Since a stable resistance can be secured, the characteristics of a semiconductor device can be stabilized.

According to the disclosure, the width of the polysilicon layer used as a resistor can be controlled, if needed, irrespective of the width of the isolation layer. Accordingly, the polysilicon layer preferably is formed to have a desired resistance when a semiconductor device is manufactured.

Furthermore, since the polysilicon layer used as a resistor is formed over the isolation layer, parasitic capacitance occurring in the active regions of the semiconductor substrate can be improved. Accordingly, the disclosure can implement the operation of a stable circuit element.

Furthermore, the metal silicide layer may not be formed over the polysilicon layer formed over the isolation layer using the step. Accordingly, since an additional mask process needs not to be performed to remove the metal silicide layer of a region in which a resistor will be formed, the resistance of the resistor can be secured, and the resistance of the control gate of a memory cell can be lowered.

The disclosure can reduce the manufacturing cost of semiconductor devices because an additional mask process needs not to be performed.

What is claimed is:

1. A resistor of a semiconductor device, the resistor comprising:
a semiconductor substrate comprising isolation layers and active regions;
a gate insulating layer and a first polysilicon layer formed over the active region;
a second polysilicon layer separated into a first pattern formed on the isolation layer, and a second pattern formed over the first polysilicon layer and higher than the first pattern;
a first interlayer dielectric layer covering the first pattern over the isolation layer;
a second interlayer dielectric layer over the first interlayer dielectric layer;
contact holes in the first and second interlayer dielectric layers exposing the first pattern; and
contact plugs filling the respective contact holes and coupled to the first pattern.

2. The resistor of claim 1, further comprising a metal silicide layer formed on the second pattern,
wherein the first interlayer dielectric layer exposes the second pattern, and
the second interlayer dielectric layer covers the metal silicide layer.

3. The resistor of claim 2, wherein the metal silicide layer is higher than the first interlayer dielectric layer.

4. The resistor of claim 1, wherein the isolation layer under the first pattern is lower than the first polysilicon layer.

5. The resistor of claim 1, wherein the isolation layer under the first pattern is 500 Å to 1500 Å lower than the first polysilicon layer.

6. The resistor of claim 1, wherein the first pattern has a thickness of 700 Å to 2000 Å.

7. The resistor of claim 1, further comprising a dielectric layer or a dielectric layer and a capping layer disposed between the first polysilicon layer and the second pattern.

8. A method of manufacturing a resistor of a semiconductor device, the method comprising:
forming a gate insulating layer and a first polysilicon layer over an active region of a semiconductor substrate that comprises isolation regions and active regions, and forming an isolation layer in the isolation region;
forming a second polysilicon layer over the first polysilicon layer and the isolation layer;
etching the second polysilicon layer to separate the second polysilicon layer into a first pattern formed on the isolation layer and a second pattern formed over the first polysilicon layer and higher than the first pattern;
forming a first interlayer dielectric layer that covers the first pattern₇ over the isolation layer;
forming a second interlayer dielectric layer over the first interlayer dielectric layer;
forming contact holes in the first and second interlayer dielectric layers, to expose the first pattern; and
forming contact plugs coupled to the first pattern within the respective contact holes.

9. The method of claim 8, wherein forming a gate insulating layer and a first polysilicon and forming an isolation layer in the isolation region comprises:
stacking the gate insulating layer and the first polysilicon layer over the isolation region and the active region;
etching the isolation region, including the first polysilicon layer, the gate insulating layer, and the semiconductor substrate;
forming the isolation layer in the etched isolation region; and
lowering a height of the isolation layer to a height less than a height of the first polysilicon layer.

10. The method of claim 8, comprising:
forming the isolation layer to be lower than the first polysilicon layer to define a step between the first polysilicon layer and the isolation layer, and
when forming the second interlayer dielectric layer over the first interlayer dielectric layer, forming the second polysilicon layer to be lower over the isolation layer than over the first polysilicon layer because of the step.

11. The method of claim 10, wherein the step has a thickness of 500 Å to 1500 Å.

12. The method of claim 8, further comprising:
before forming the second polysilicon layer, forming a dielectric layer on the isolation layer and the first polysilicon layer; and removing the dielectric layer formed on the isolation layer.

13. The method of claim 12, wherein removing the dielectric layer formed on the isolation layer comprises:
forming a capping layer on the dielectric layer formed on the first polysilicon layer; and
etching the dielectric layer using the capping layer as a barrier.

14. The method of claim 8, further comprising etching the second polysilicon layer formed over the isolation layer the first interlayer dielectric layer, before separating the second polysilicon layer into the first and second patterns after forming the second polysilicon layer.

15. The method of claim 8, wherein forming a first interlayer dielectric layer covering the first pattern over the isolation layer comprises:
forming the first interlayer dielectric layer over the isolation layer and the second pattern;
polishing a surface of the first interlayer dielectric layer to expose the second pattern; and
forming a metal silicide layer on the second pattern.

16. The method of claim 15, further comprising lowering a height of the first interlayer dielectric layer to expose sidewalls of the second pattern before forming the metal silicide layer after polishing the surface of the first interlayer dielectric layer.

17. The method of claim 8, comprising forming the second polysilicon layer to a thickness of 700 Å to 2000 Å.
